(19) United States
(12) Patent Application Publication
(10) Pub. No.: US 2005/0037291 A1
(43) Pub. Date: Feb. 17, 2005

(54) Method for forming fine resist pattern

(76) Inventors: Kazuyuki Nitta, Kawasaki-shi (JP); Satoshi Shimatani, Kawasaki-shi (JP); Masahiro Masujima, Kawasaki-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/497,016

(22) PCT Filed: Dec. 2, 2002
(86) PCT No.: PCT/JP02/12604

(30) Foreign Application Priority Data
Dec. 3, 2001 (JP) 2001-369110

(51) Int. Cl. G03F 7/40

(52) U.S. Cl. 430/330; 430/322; 430/326

(57) ABSTRACT

The object is to form a resist pattern to be applicable to a thermal flow process with a small changing amount of the resist pattern size per unit temperature, high uniformity within the plane of the resist hole pattern size obtained and an excellent cross sectional profile. In a resist pattern forming method by subjecting a patterned positive-working resist film provided on a substrate to a thermal flow treatment to effect size reduction, it is characterized in (a) that, as the positive-working resist composition to be used, a positive-working resist composition is used which comprises (A) a resinous ingredient capable of being imparted with increased solubility in alkali by an acid, (B) a compound generating an acid by irradiation with a radiation, (C) a compound having at least two vinyl ether groups per molecule to form crosslinks by reacting with the resinous ingredient (A) under heating and (D) an organic amine compound and (b) that the aforemen-tioned thermal flow treatment is conducted by twice or more of heatings within a temperature range of 100-200° C. wherein the temperature of subsequent heating is not lower than the temperature in the preceding heating.

### TECHNOLOGICAL FIELD

The present invention relates to an improvement in a method for the preparation of a fine resist pattern which is size-reduced by utilizing the thermal flow process or, to say in more particulars, to an improved method in which control of the resist pattern size can be conducted in high accuracy by a thermal flow process decreasing the size reduction of the resist pattern per unit temperature.

### BACKGROUND TECHNOLOGY

While, in the production of semiconductor devices such as ICs and LSIs and liquid crystal devices such as LCDs, the photolithographic technology is utilized by using a radiation such as light, the pattern resolution therein depends on the wavelength of the radiation to be used and the numerical aperture (NA) of the projection optical system.

Along with the increasing demand in recent years toward compactness of devices, the radiation used is on the way of the direction toward a shorter wavelength from the i-line (365 nm) to the KrF excimer laser beams (248 nm) or ArF excimer laser beams (193 nm) and, according thereto, studies to have an increased numerical aperture of the projection optical system are now under way but the pattern resolving power is under limitation even by increasing the numerical aperture because an increase in the numerical aperture is accompanied by a decrease in the focusing depth.

As a means for increasing fineness of the resist pattern in the lithographic method, on the other hand, it is in recent times that proposals are made for the so-called thermal flow process in which a resist film is subjected to a pattern-forming light-exposure and development treatment followed by a heating treatment of the thus obtained resist pattern to cause a flow so as to form a resist pattern of a size smaller than the size of the resist pattern after the development (Japanese Patent Kokai No. 2000-188250 and Japanese Patent Kokai No. 2000-356850).

While this thermal flow process is advantageous because an increase in fineness can be accomplished by using existing resist materials, it is essential to accurately control the changing amount in the resist pattern size per unit temperature since the flow of the resist pattern as developed is caused by heat so that a resist composition having properties suitable thereto is required.

For such a material, a proposal is made heretofore for a chemical-amplification positive-working resist composition by formulating with a compound having at least two vinyl ether groups (Japanese Patent Kokai No. 9-274320) but this material is defective because the pattern has a trapezoidal profile of the cross section despite the advantage of an improved pattern resolution.

Since then, a proposal has been made, as a method for the formation of a fine resist hole pattern in which the changing amount of the resist pattern size per unit temperature in the application of the thermal flow process is controlled along with suppression of dimples formed in the formation of a resist pattern by the photolithographic method using a halftone phase-shift photomask, for a method in which the resist pattern size is reduced by forming a resist film on a substrate using a positive-working resist composition consisting of (A) a resinous ingredient capable of being imparted with increased solubility in alkali by an acid, (B) a compound generating an acid by irradiation with a radiation, (C) a compound having at least two vinyl ether groups forming crosslinks by reacting with the resinous ingredient (A) under heating and (D) an organic amine and irradiating this resist film through a halftone phase-shift photomask followed by heating of the resist pattern obtained by alkali development. Even by way of this method, it is still difficult to strictly suppress the size decreasing amount of the resist pattern per unit temperature in conducting thermal flow and, nevertheless, to obtain a resist pattern having a good cross sectional profile or to suppress occurrence of variations in the hole sizes by heating errors in conducting thermal flow of a plurality of hole resist patterns formed on a single substrate.

### DISCLOSURE OF THE INVENTION

The present invention has been made with an object, under these circumstances, to form a resist pattern exhibiting a small changing amount of the resist pattern size per unit temperature to be suitable to the thermal flow process, by which the resist hole pattern obtained has high uniformity of size within the plane and has an excellent cross sectional profile.

The inventors have conducted extensive investigations on a method for the formation of a fine resist pattern by utilizing the thermal flow process and have arrived at a discovery that there can be provided a fine resist pattern with uniformity in the configuration of trenches or holes and good cross sectional profile of the resist pattern enabling strict control of the resist pattern size with minimization of the size change of the resist pattern per unit temperature in the thermal flow by using a specified chemical-amplification positive-working resist composition and conducting the thermal flow treatment in plural times of heating, thus leading to completion of the present invention on the base of this discovery.

Namely, the present invention provides a method for the formation of a fine resist pattern which is characterized in that, in a method for the formation of a resist pattern in which a resist pattern obtained as formed by successively undertaking a pattern-wise light-exposure treatment and a development treatment of a positive-working resist film provided on a substrate, (1) the above-mentioned positive-working resist should be a positive-working resist composition consisting of (A) a resinous ingredient capable of being imparted with increased solubility in alkali by an acid, (B) a compound generating an acid by irradiation with a radiation, (C) a compound having, in a molecule, at least two vinyl ether groups forming crosslinks by reacting with the resinous ingredient (A) under heating and (D) an organic amine, and (2) the above-mentioned thermal flow treatment is conducted by heating twice or more within the temperature range from 100 to 200° C., provided that the following heating temperature should not be lower than the previous heating temperature.

### BEST MODE FOR PRACTICING THE INVENTION

It is essential in the present invention to form a positive-working resist film on a substrate using a positive-working resist composition consisting of (A) a resinous ingredient capable of being imparted with increased solubility in alkali by an acid, (B) a compound generating an acid by irradiation with a radiation, (C) a compound having at least two vinyl ether groups forming crosslinks by reacting with the resinous ingredient (A) under heating and (D) an organic amine.

Examples of the resin, which is imparted with increased solubility in alkali by interacting with the acid as this component (A), include those known resins used in positive resist for KrF such as hydroxystyrene copolymers containing hydroxystyrene units substituted for the hydrogen atoms of the hydroxyl groups with acid-dissociable groups, copolymers containing acrylic acid or methacrylic acid units substituted for the hydrogen atoms of the carboxyl groups with acid-dissociable groups and hydroxystyrene units and the like, and those known resins used in positive resists for ArF such as non-aromatic resins having, in the main chains or side chains, polycyclic hydrocarbon groups having acid-dissociable groups and others, of which copolymers containing hydroxystyrene units substituted for the hydrogen atoms of the hydroxyl groups with acid-dissociable groups and hydroxystyrene units are particularly preferable in the resists for KrF excimer laser for low-temperature baking.

Meanwhile, the aforementioned hydroxystyrene unit can be a hydroxy-α-methylstyrene unit.

By virtue of these hydroxystyrene units substituted for the hydrogen atoms of the hydroxyl groups with acid-dissociable solubility-reducing groups or similarly substituted hydroxy-α-methylstyrene units, conversion is caused in the light-exposed areas into phenolic hydroxyl groups by inter-action with the acid generated by irradiation with radiation so as to have the solubility-reducing groups dissociated. In this way, the resin which was alkali-insoluble before the light-exposure is rendered alkali-soluble after the light-exposure.

The hydroxystyrene or hydroxy-α-methylstyrene units are to impart alkali-solubility. The position of the hydroxyl group can be any of the o-position, m-position and p-position but the p-position is the most preferable in respect of good availability and low price.

The aforementioned acid-dissociable solubility-reducing group can be freely selected from those proposed as an acid-dissociable solubility-reducing group in the ingredient imparted with increased solubility to alkali by inter-action with an acid in the chemical-amplification type resists for KrF or ArF. Preferable among them are those groups selected from among tertiary alkyloxycarbonyl groups, tertiary alkyloxycarbonylalkyl groups, tertiary alkyl groups, cyclic ether groups, alkoxyalkyl groups, 1-alkylmonocycloalkyl groups and 2-alkylpolycycloalkyl groups.

The tert-alkyloxycarbonyl group is exemplified by tert-butyloxycarbonyl group, tert-amyloxycarbonyl group and the like. The tert-alkyloxycarbonylalkyl group is exemplified by tert-butyloxycarbonylmethyl group, tert-butyloxycarbonylethyl group, tert-amyloxycarbonylmethyl group, tert-amyloxycarbonylethyl group and the like. The tert-alkyl group is exemplified by tert-butyl group, tert-amyl group and the like. The cyclic ether group is exemplified by tetrahydropyranyl group, tetrahydrofuranyl group and the like. The alkoxyalkyl group is exemplified by 1-ethoxyethyl group, 1-methoxypropyl group and the like. The 1-alkyl monocycloalkyl group is exemplified by 1-(lower alkyl) cyclohexyl groups having a cyclic group formed by conjoining of two alkyl groups bonded to the tertiary carbon atom such as 1-methylcyclohexyl group and 1-ethylcyclohexyl group. The 2-alkyl polycycloalkyl group is exemplified by 2-(lower alkyl) adamantyl groups having a polycyclic hydrocarbon group formed by conjoining of two alkyl groups bonded to the tertiary carbon atom such as 2-methyladamantyl group and 2-ethyladamantyl group.

In particular, preferable hydroxystyrene copolymers include a polyhydroxystyrene having a mass-average molecular weight of 2000 to 30000 with a molecular weight dispersion of 1.0 to 6.0 of which 10 to 60% of the hydroxyl hydrogen atoms are substituted by acid-dissociable groups selected from tert-butyloxycarbonyl group, tert-butyloxycarbonylmethyl group, tert-butyl group, tetrahydropyranyl group, tetrahydrofuranyl group, 1-ethoxyethyl group and 1-methoxypropyl group.

Particularly suitable as the component (A) in respect of the pattern resolution and cross sectional profile of the resist pattern is a mixture of (a₁) a hydroxystyrene-based copolymer containing 10 to 60% by moles or, preferably, 10 to 50% by moles of tert-butyloxycarbonyloxystyrene units and having a mass-average molecular weight of 2000 to 30000 or, preferably, 5000 to 25000 with a molecular weight dispersion of 1.0 to 6.0 or, preferably, 1.0 to 4.0 and (a₂) a hydroxystyrene-based copolymer containing 10 to 60% by moles or, preferably, 10 to 50% by moles of alkoxyalkyloxystyrene units and having a mass-average molecular weight of 2000 to 30000 or, preferably, 5000 to 25000 with a molecular weight dispersion of 1.0 to 6.0 or, preferably, 1.0 to 4.0, in which the mass proportion is in the range of 10:90 to 90:10 or, preferably, 10:90 to 50:50.

Also suitable is a mixture of (a₃) a hydroxystyrene-based copolymer containing 10 to 60% by moles or, preferably, 10 to 50% by moles of tetrahydropyranyloxystyrene units and having a mass-average molecular weight of 2000 to 30000 or, preferably, 5000 to 25000 with a molecular weight dispersion of 1.0 to 6.0 or, preferably, 1.0 to 4.0 and the above-described copolymer (a₂) in which the mass proportion is in the range of 10:90 to 90:10 or, preferably, 10:90 to 50:50.

Further suitable is a mixture of (a₄) a hydroxystyrene-based copolymer containing 10 to 60% by moles or, preferably, 10 to 50% by moles of tert-butyloxystyrene units and having a mass-average molecular weight of 2000 to 30000 or, preferably, 5000 to 25000 with a molecular weight dispersion of 1.0 to 6.0 or, preferably, 1.0 to 4.0 and the above-described copolymer (a₂) in which the mass proportion is in the range of 10:90 to 90:10 or, preferably, 10:90 to 50:50.

Further, preferable as the component (A) in a resist for KrF excimer laser for high-temperature baking is a copolymer containing the units of acrylic acid or methacrylic acid substituted by acid-dissociable groups for the hydrogen atoms of the carboxyl groups and hydroxystyrene units. The acid-dissociable group here in the component (A) is selected from the aforementioned ones but it is particularly preferable to be a tertiary alkyl group such as tert-butyl group, 1-(lower alkyl) cyclohexyl group such as 1-methylcyclohexyl group and 1-ethylcyclohexyl group or a 2-(lower alkyl) polycycloalkyl group such as 2-methyladamantyl group and 2-ethyladamantyl group.

In respects of excellent pattern resolution, resist pattern profile and etching resistance, among them, preferable are those in the ranges of a mass-average molecular weight from 2000 to 30000 or, preferably, from 5000 to 25000, molecular weight dispersion from 1.0 to 6.0 or, preferably, from 1.0 to 4.0 and containing 40 to 80% by moles or, preferably, 50 to 70% by moles of hydroxystyrene units, 10 to 40% by moles or, preferably, 15 to 30% by moles of styrene units and 2 to 30% by moles or, preferably, 5 to 20% by moles of acrylic acid or methacrylic acid substituted by acid-dissociable groups. The aforementioned hydroxystyrene units and styrene units can be hydroxy-α-methylstyrene units and α-methylstyrene units.

Incidentally, the resist for low-temperature baking is subjected to the prebaking and post-exposure baking (PEB) at a temperature between 90 and 120° C. or, preferably, 90 and 110° C., respectively, and the resist for high-temperature baking is subjected to prebaking and post-exposure baking (PEB) at a temperature selected from between 110 and 150° C. or, preferably, 120 and 140° C., respectively.

In the next place, the component (B), which is a compound capable of releasing an acid when irradiated with a radiation such as ultraviolet light, can be freely selected from the compounds used as an acid-generating agent in the chemical-amplification positive-working resist compositions of the prior art without particular limitations. Such an acid-generating agent includes diazomethane compounds, nitrobenzyl derivatives, sulfonic acid esters, onium salt compounds, benzoin tosylate compounds, halogen-containing triazine compounds, cyano group-containing oximesulfonate compounds and the like, of which diazomethane compounds and onium salt compounds of which the anionic counterpart is a halogenoalkyl sulfonic acid having 1 to 15 carbon atoms are suitable.

Examples of the diazomethane compound include bis(p-toluenesulfonyl)diazomethane, bis(1,1-dimethylethylsulfonyl)diazomethane, bis(cyclohexylsulfonyl)diazomethane, bis(2,4-dimethylphenylsulfonyl)diazomethane and the like. Examples of the onium salt compound of which the anionic counter part is a halogenoalkyl sulfonic acid having 1 to 15 carbon atoms include diphenyliodonium trifluoromethanesulfonate or nonafluorobutanesulfonate, bis(4-methoxyphenyl)iodonium trifluoromethanesulfonate or nonafluorobutanesulfonate, bis(p-tert-butylphenyl)iodonium trifluoromethanesulfonate or nonafluorobutanesulfonate, triphenylsulfonium trifluoromethanesulfonate or nonafluorobutanesulfonate, (4-methoxyphenyl)diphenylsulfonium trifluoromethanesulfonate or nonafluorobutanesulfonate, (p-tert-butylphenyl)diphenylsulfonium trifluoromethanesulfonate or nonafluorobutanesulfonate and the like.

These acid-generating agents as the component (B) can be used singly or can be used as a combination of two kinds or more. The amount thereof can be usually selected in the range from 1 to 20 parts by mass per 100 parts by mass of the above-mentioned component (A). When the amount of the component (B) is smaller than 1 part by mass, image formation cannot be accomplished while, when the amount exceeds 20 parts by mass, the photoresist composition can hardly be in the form of a uniform solution so as to suffer low storage stability.

While it is essential in the present invention to contain a compound having, in a molecule, at least two crosslinkable vinyl ether groups as the component (C), this material can be one that is susceptible to thermal crosslinking with the base resin ingredient when a resist film is formed by applying the resist on a substrate followed by drying without particular limitations. A particularly preferable component (C) is a compound which is a polyoxyalkyleneglycol such as alkyleneglycols, dialkyleneglycols, trialkyleneglycols and the like or a polyhydric alcohol such as trimethylolpropane, pentaerithritol, pentaglycol and the like substituted by vinyl ether groups for at least two hydroxyl groups.

Such a compound includes, for example, ethyleneglycol divinyl ether, diethyleneglycol divinyl ether, triethyleneglycol divinyl ether, 1,4-butanediol divinyl ether, tetramethyleneglycol divinyl ether, tetraethyleneglycol divinyl ether, neopentylglycol divinyl ether, trimethylolpropane trivinyl ether, trimethylolethane trivinyl ether, hexanediol divinyl ether, 1,4-cyclohexanediol divinyl ether, pentaerythritol divinyl ether, pentaerythritol trivinyl ether, cyclohexanedimethanol divinyl ether and the like.

Polyhydric alcohol divinyl ethers having an alicyclic group such as cyclohexanedimethanol divinyl ether are particularly preferable among those compounds.

This compound as the component (C) having, in a molecule, at least two crosslinkable vinyl ether groups is added in the range, usually, from 0.1 to 25 parts by mass or, preferably, from 1 to 15 parts by mass per 100 parts by mass of the aforementioned component (A). They can be used singly or can be used as a mixture of two kinds or more.

An organic amine as the component (D) in the positive-working resist composition is compounded for rendering the positive-working resist solution composition solution basic to effect stabilization and secondary or tertiary aliphatic amines are preferable. Such an amine includes dimethylamine, trimethylamine, diethylamine, triethylamine, tri-n-propylamine, triisopropylamine, tri-n-butylamine, triisobutylamine, tri-tert-butylamine, tripentylamine, diethanolamine, triethanolamine, tributanolamine and the like. Dialkanolamines or trialkanolamine such as diethanolamine, triethanolamine, tributanolamine and the like are preferable among them.

The amine compounds as this component (D) is usually used in the range from 0.01 to 1 part by mass or, preferably, from 0.05 to 0.7 part by mass per 100 parts by mass of the component (A). These can be used singly or can be used as a combination of two kinds or more.

When used, this positive-working resist composition is preferably used in the form of a solution prepared by dissolving each of the above-described components in a solvent. Examples of solvents used in this case include ketones such as acetone, methyl ethyl ketone, cyclohexanone, methyl isoamyl ketone, 2-heptanone and the like, polyhydric alcohols and derivatives thereof such as ethyleneglycol, ethyleneglycol monoacetate, diethyleneglycol, diethyleneglycol monoacetate, propyleneglycol, propyleneglycol monoacetate, dipropyleneglycol or dipropyleneglycol monoacetate as well as monomethyl ether, monoethyl ether, monopropyl ether, monobutyl ether or monophenyl ether thereof, cyclic ethers such as dioxane and the like and esters such as methyl lactate, ethyl lactate, methyl acetate, ethyl acetate, butyl acetate, methylpyruvate, ethyl pyruvate, methyl methoxypropionate, ethyl ethoxypropionate and the like. These can be used singly or can be used as a mixture of two kinds or more.

This composition can be admixed according to desire further with additives having miscibility such as, for example, auxiliary resins to improve resist film properties, plasticizers, stabilizers, coloring agents, surface-active agents and others, which are conventionally used.

In the inventive method, according to desire, an inorganic or organic antireflection film can be provided between the substrate and the resist film. Thereby, the pattern resolution can be further increased and the so-called substrate dependency which is a phenomenon that the profile of the resist pattern is adversely affected as a result of the influence of the substrate on a variety of thin films (SiN, TiN, BPSG and the like) provided thereon, can be suppressed.

The inorganic antireflection film material is exemplified by SiON and the like and the organic antireflection film is exemplified by SWK Series (each a product by Tokyo Ohka Kogyo Co.), DUV Series (each a product by Brewer Science Co.), AR Series (each a product by Shipley Co.) and the like.

In the method of the present invention, nextly, the positive-working resist film can be provided on the substrate in the same manner as in the known method for the resist pattern formation. Namely, a substrate such as a silicon wafer or a substrate provided according to need with an antireflection film is coated with a solution of the resist composition with a spinner and the like followed by drying to form a resist film.

Nextly, the pattern-wise light-exposure treatment and the development treatment in the method of the present invention can be performed in just the same way as in the conventional known resist pattern formation. Namely, the pattern-wise light-exposure treatment is conducted by irradiating the positive-working resist film with a radiation through a photomask of a specified pattern. The radiation usable here is exemplified by ultraviolet light, ArF excimer laser beams, KrF excimer laser beams and the like. The positive-working resist film after the light exposure, in which a latent image is formed by the pattern-wise light-exposure treatment in this way, is subjected to a heat treatment followed by development in which the light-exposed areas are dissolved and removed by using an aqueous alkaline solution such as a 0.1-10% by mass aqueous solution of tetramethylammonium hydroxide.

In the present invention, it is essential that the resist pattern obtained by the development treatment in such a manner is subjected to a thermal flow treatment. This thermal flow treatment is conducted by heating twice or more or, preferably, twice or thrice. It is preferable in this case that the number of times is increased because the resist pattern size variation is decreased thereby per unit temperature although the throughput is decreased due to increase in the number of steps for increasing the times.

This heat treatment is performed at a temperature in the range of 100-200° C. or, preferably, 110-180° C. and it is necessary that the heating temperature in the second time and thereafter is set to be the same temperature as in the first time or higher.

The reason for undertaking twice or more of the heat treatment in the inventive method is that crosslinks are formed in the first heating by the component (C) in the positive-working resist so as to increase the glass transition temperature (Tg) of the thus formed resist film so that the desired resist pattern size reduction is accomplished by the heating of the second time and thereafter.

Since the resist film formed in the first time heating exhibits decreased thermal changes, in this way, the amount of resist pattern size reduction per unit temperature is decreased in the heat treatment of the second time and thereafter. In the same time, it is possible by these heat treatments that the cross sectional profile of the resist pattern is brought to orthogonal even if it had been trapezoidal after the development.

When the desired resist pattern size reduction is caused by the first time heating only, the amount of the resist pattern size changes is so large that uniformity of the thus obtained resist pattern size is degraded within the plane.

The optimum heating temperature which depends on the composition of the resist film is in the range of 110-180° C. in each time independently from the others.

A preferable embodiment of the inventive method is a method in which the component (A) used is a mixture of a polyhydroxystyrene substituted by tert-butoxycarbonyl groups for the hydrogen atoms of a part of the hydroxyl groups and a polyhydroxystyrene substituted by 1-ethoxyethyl groups for the hydrogen atoms of a part of the hydroxyl groups or a mixture of a polyhydroxystyrene substituted by tetrahydropyranyl groups for the hydrogen atoms of a part of the hydroxyl groups and a polyhydroxystyrene substituted by 1-ethoxyethyl groups for the hydrogen atoms of a part of the hydroxyl groups and the thermal flow treatment is conducted with a first time heating in the range of 120-150° C. and a second time heating in the range of 130-160° C.

The heating time in this case can be in such a range without particular limitations that the throughput is not adversely affected and a desired resist pattern size is obtained but, when the line steps for the manufacture of conventional semiconductor devices are taken into consideration, it should be about 30-270 seconds or, preferably, 60-120 seconds for each of the heating temperatures.

The amount of the resist pattern size reduction per unit temperature in the inventive method can be determined in the following manner.

Thus, after development, 10 wafers provided with a resist pattern of, for example, 200 nm width are prepared and they are subjected to heating for 90 seconds at the respective temperatures (9 points) between 124 and 140° C. with 2° C. increments. Thereby the resist patterns are size-reduced respectively at each of the temperatures. A graph is prepared for the relationship between the temperature and the reduced resist pattern size by taking the changing amount of the resist pattern size as the ordinate and the temperature changes as the abscissa. Thereafter, calculation can be made by dividing the changing amount (nm) of the resist pattern in the vicinity of the target resist pattern size of, for example, 150 nm by the changing amount (° C.) of temperature corresponding thereto.

The influence of the resist film thickness on the changing amount of size is not so great provided that it does not exceed 1000 nm. A preferable resist film thickness is 1000 nm or smaller or, in particular, 400-850 nm. The resist film thickness should preferably be small enough because, as a trend, the pattern resolution is improved with a decrease in the thickness and the flow rate can be in the range of 2-15 nm/° C.

It is preferable that the method of the present invention is performed by controlling in such a way that the changing amount of the resist pattern size by the heat in the first time be 15 nm/° C. or smaller and the changing amount of the resist pattern size by heating in the second time and thereafter be 3-10 nm/° C.

In the following, the present invention is described in more details by way of examples but the present invention is never limited by these examples in any way.

Meanwhile, the various properties of the positive-working resist compositions shown in the respective examples were obtained by the following methods.

(1) Sensitivity:

The resist composition as prepared was applied by using a spinner onto a silicon wafer provided with an antireflection film SWK-EX2 (produced by Tokyo Ohka Kogyo Co.) in a film thickness of 120 nm and the same was subjected to heat-drying at 90° C. for 90 second on a hot plate to obtain a resist film of 500 nm film thickness. By using a minifying projection light-exposure machine FPA-3000EX3 (manufactured by Canon Co.), this film was light-exposed through a halftone phase-shift photomask with KrF excimer laser beams in doses with additions of each 1 mJ/cm² increment followed by post-exposure baking (PEB) at 110° C. for 90 seconds, development with a 2.38% by mass aqueous solution of tetramethylammonium hydroxide at 23° C. taking 60 seconds, water-rinse for 30 seconds and dried and the minimum light-exposure dose by which the film thickness after development in the light-exposed areas at 0 determined in the unit of mJ/cm² (amount of energy) was taken as the sensitivity.

(2) Resist Pattern Profile 1 (Immediately After Development):

A resist hole pattern of 250 nm diameter obtained by the same procedure as in (1) above was examined with SEM (scanning electron microscope) and the profile thereof was evaluated to give A to a hole pattern having orthogonality to the substrate bottom and B to a tapered profile.

(3) Resist Pattern Profile 2 (After Thermal Flow)

A resist hole pattern of 250 nm diameter obtained by the same procedure as in (1) above was subjected to a thermal flow treatment and then examined by SEM (scanning electron microscope) and the profile thereof was evaluated to give A to a hole pattern having orthogonality to the substrate bottom and B to a poor profile.

(4) Pattern Resolution:

The critical pattern resolution (nm) was determined for a resist hole pattern obtained by the same procedure as in (1) above.

(5) Thermal Flow Characteristics:

A resist hole pattern of 200 nm diameter obtained by the same procedure as in (1) above was subjected to the first to third heat treatments shown in Table 1 to find contraction down to 120 nm. The flow rates (changing amount of the resist pattern size per 1° C.) of the thus formed 120 nm resist pattern were measured in nm/° C. and evaluated by the following criteria.
A: less than 5 nm/° C.
B: 5 nm/° C. or more but less than 10 nm/° C.
C: 10 nm/° C. or more

### EXAMPLE 1

A positive-working resist composition was prepared by adding, to a mixture of 75 parts by mass of a first polyhydroxystyrene having a mass-average molecular weight of 10000 with a molecular weight dispersion of 1.2, of which 39% of the hydroxyl hydrogen atoms were substituted by 1-ethoxyethyl groups, and 25 parts by mass of a second polyhydroxystyrene having a mass-average molecular weight of 10000 with a molecular weight dispersion of 1.2, of which 36% of the hydroxyl hydrogen atoms were substituted by tert-butoxycarbonyl groups, 5 parts by mass of bis(cyclohexylsulfonyl) diazomethane, 5 parts by mass of 1,4-cyclohexanedimethanol divinyl ether, 0.2 part by mass of triethanolamine and 0.05 part by mass of a fluorosilicone-based surface active agent to be dissolved in 490 parts by mass of propyleneglycol monomethyl ether acetate followed by filtration through a membrane filter of 200 nm pore diameter.

Nextly, the surface of a silicon wafer (200 mm diameter and 0.72 mm thickness) provided with an antireflection film (“SWK-EX2”, a product by Tokyo Ohka Kogyo Co.) of 120 nm thickness was coated by using a spinner with the aforementioned positive-working resist composition followed by dryheating on a hot plate at 90° C. for 90 seconds to form a resist film having a thickness of 500 nm.

The resist film obtained in thus way was evaluated for the sensitivity, resist pattern profile and pattern resolution followed by irradiation with KrF excimer laser beams through a halftone phase-shift photomask by using a minifying projection light-exposure machine (“FPA-3000EX3”, manufactured by Canon Co.) followed by post-exposure baking (PEB) at 110° C. for 90 seconds followed by development by dipping for 60 seconds in a 2.38% by mass aqueous solution of tetramethylammonium hydroxide kept at 23° C. and rinse with water for 30 seconds to obtain a resist hole pattern of 250 nm diameter.

In the next place, the thus obtained resist hole pattern was subjected to a thermal flow treatment by heating first at 140° C. for 90 seconds and then at 150° C. for 90 seconds. The resist pattern profiles of the thus contracted resist hole pattern before and after the thermal flow treatment are shown in Table 1 together with the various properties of the resist film evaluated before.

### EXAMPLE 2

A fine resist pattern was formed by the treatments in the same manner as in Example 1 excepting for the use of a resist composition which was the positive-working resist composition of Example 1 with additional admixture of 2 parts by mass of triphenylsulfonium trifluoromethane sulfonate as the acid-generating agent. The various properties in this case are shown in Table 1.

### EXAMPLE 3

A resist pattern was formed by preparing a positive-working resist composition in the same manner as in Example 1 excepting for the use of 100 parts by mass of the first polyhydroxystyrene only without using the second polyhydroxystyrene in Example 1 and by using the same followed by a thermal flow treatment by heating first at 140° C. for 90 seconds and then at 140° C. for 90 seconds to obtain a fine resist pattern. The various properties in this case are shown in Table 1.

### EXAMPLE 4

A fine resist pattern was formed by the treatments in the same manner as in Example 3 excepting for the use of a resist composition which was the positive-working resist composition of Example 3 additionally admixed with 2 parts by mass of triphenylphosphonium trifluoromethane sulfonate as the acid-generating agent. The various properties in this case are shown in Table 1.

### EXAMPLE 5

A positive-working resist composition was prepared in the same manner as in Example 1 excepting for the use of, in place of the resin mixture in Example 1, a mixture of 70 parts by mass of the first polyhydroxystyrene and 30 parts by mass of a third polyhydroxystyrene having a mass-average molecular weight of 10000 with a molecular weight dispersion of 1.2, of which 30% of the hydroxyl hydrogen atoms were substituted by tetrahydropyranyl groups. Properties for this material are shown in Table 1.

In the next place, a resist hole pattern was formed in the same manner as in Example 1 by using the thus obtained positive-working resist composition followed by a thermal flow treatment by heating first at 130° C. for 90 seconds and then at 150° C. for 90 seconds to obtain a fine resist pattern. The various properties in this case are shown in Table 1.

### EXAMPLE 6

A fine resist pattern was formed by the treatments in the same manner as in Example 5 excepting for the use of a resist composition which was the positive-working resist composition of Example 5 with additional admixture of 2 parts by mass of triphenylsulfonium trifluoromethane sulfonate as the acid-generating agent. The various properties in this case are shown in Table 1.

### EXAMPLE 7

A positive-working resist composition was prepared in the same manner as in Example 1 excepting for the use of, in place of the resin mixture in Example 1, a mixture of 75 parts by mass of the first polyhydroxystyrene and 25 parts by mass of a fourth polyhydroxystyrene having a mass-average molecular weight of 10000 with a molecular weight dispersion of 1.2, of which 30% of the hydroxyl hydrogen atoms were substituted by tert-butyl groups. The properties for this material are shown in Table 1.

In the next place, a resist hole pattern was formed in the same manner as in Example 1 by using the thus obtained positive-working resist composition followed by a thermal flow treatment by heating first at 140° C. for 90 seconds and then at 150° C. for 90 seconds to obtain a fine resist pattern. The various properties in this case are shown in Table 1.

### EXAMPLE 8

A fine resist pattern was formed in the same manner as in Example 7 excepting for the use of a resist composition which was the positive-working resist composition of Example 7 with additional admixture of 2 parts by mass of triphenylsulfonium trifluoromethane sulfonate as the acid-generating agent. The various properties in this case are shown in Table 1.

### EXAMPLE 9

A fine resist pattern was obtained in the same manner as in Example 1 except that the thermal flow treatment in Example 1 was undertaken by heating at 140° C. for 90 seconds, at 145° C. for 90 seconds and at 150° C. for 90 seconds. The various properties in this case are shown in Table 1.

### COMPARATIVE EXAMPLE 1

A fine resist pattern was obtained in the same manner as in Example 1 except that the thermal flow treatment in Example 1 was modified to a single time only of heating at 140° C. for 90 seconds. The various properties in this case are shown in Table 1.

### COMPARATIVE EXAMPLE 2

A positive-working resist composition was prepared in the same manner as in Example 1 except that the cyclohexane dimethanol divinyl ether was not used. Table 1 shows the various properties of the fine resist pattern obtained in the same manner as in Example 1 by using this resist composition.

TABLE 1

| | | | Resist pattern | | | | | | |
|---|---|---|---|---|---|---|---|---|---|
| | | | profile | | | | | | |
| | | | Imme- | After | | Termal flow treatment | | | |
| | | | diately | thermal | Pattern | | | | Changing |
| | | Sensi- | after | flow | reso- | | | | amount of |
| | | tivity | develop- | treat- | lution | Heating conditions | | | pattern |
| | | (mJ/cm²) | ment | ment | (nm) | 1st | 2nd | 3rd | size |
| Exam- | 1 | 40 | A | A | 180 | 140° C., | 150° C., | — | A |
| ple | | | | | | 90s | 90s | | |
| | 2 | 30 | B | A | 170 | 140° C., | 150° C., | — | A |
| | | | | | | 90s | 90s | | |
| | 3 | 35 | A | A | 170 | 140° C., | 140° C., | — | A |
| | | | | | | 90s | 90s | | |
| | 4 | 30 | B | A | 170 | 140° C., | 140° C., | — | A |
| | | | | | | 90s | 90s | | |
| | 5 | 42 | A | A | 180 | 130° C., | 150° C., | — | B |
| | | | | | | 90s | 90s | | |
| | 6 | 40 | B | A | 170 | 130° C., | 150° C., | — | B |
| | | | | | | 90s | 90s | | |
| | 7 | 44 | A | A | 180 | 140° C., | 150° C., | — | A |
| | | | | | | 90s | 90s | | |
| | 8 | 40 | B | A | 170 | 140° C., | 150° C. | — | B |
| | | | | | | 90s | 90s | | |
| | 9 | 30 | A | A | 180 | 140° C., | 145° C., | 150° C. | A |
| | | | | | | 90s | 90s | 90s | |
| Com- | 1 | 42 | A | A | 180 | 140° C., | — | — | C |
| para- | | | | | | 90s | | | |
| tive | | | | | | | | | |
| Exam- | 2 | 35 | A | A | 180 | 140° C., | 150° C., | — | C |
| ple | | | | | | 90s | 90s | | |

### INDUSTRIAL UTILIZABILITY

According to the method of the present invention, the changing the amount of the resist pattern size per unit temperature can be decreased so that a fine resist pattern can be formed with enhanced uniformity of the pattern size within plane and excellent cross sectional profile.

1. A method characterized in that, in a method for the formation of a size-reduced patterned photoresist layer by subjecting a patterned photoresist layer of a positive-working photoresist composition on a substrate surface to a thermal flow treatment,
(a) the aforementioned positive-working photoresist composition comprises (A) a resin compound capable of being imparted with increased solubility in an aqueous alkaline solution by interacting with an acid, (B) a compound capable of generating an acid by irradiation with a radiation, (C) a compound having, per molecule, at least two vinyl ether residues capable of forming crosslinks by reacting with the resin compound as the component (A) under heating and (D) an organic amine compound, and
(b) the aforementioned thermal flow treatment is conducted by at least twice of a heating treatment steps of the patterned photoresist layer at a temperature in the range of 100 to 200° C., and the temperatures in the second and subsequent heat treatments are each not lower than the temperature in the preceding heat treatment.

2. The method described in claim 1 wherein the said positive-working photoresist composition contains 0.1 to 25 parts by mass and 0.01 to 1 part by mass of the component (C) and component (D), respectively, per 100 parts by mass of the component (A).

3. The method described in claim 1 wherein the length of time taken for each of the heat treatments is set in the range of 30 to 270 seconds.

4. The method for the formation of a fine resist pattern described in claim 1 wherein the size-reducing amounts of the patterned photoresist layer by heating per unit temperature are set within the ranges of 15 nm/° C. or less for the first time heat treatment and 3 to 10 nm/° C. for each time of the second time and subsequent heat treatments.
